(19) United States
(12) Patent Application Publication
(10) Pub. No.: US 2012/0118733 A1
(43) Pub. Date: May 17, 2012

(54) MAGNETRON SPUTTERING APPARATUS

(75) Inventor: Masao SASAKI, Hachioji-shi (JP)

(73) Assignee: CANON ANELVA CORPORATION, Kawasaki-shi (JP)

(21) Appl. No.: 13/276,368

(22) Filed: Oct. 19, 2011

(30) Foreign Application Priority Data
Nov. 12, 2010 (JP) 2010-253855

(51) Int. Cl. C23C 14/35; C23C 14/54

(52) U.S. Cl. 204/298.11; 204/298.2

(57) ABSTRACT

A magnetron sputtering apparatus includes a process chamber, a substrate conveyer provided in the process chamber to convey a substrate, a target holder provided in the process chamber to hold a flat target, a magnet unit arranged on a back side of the target holder, an electric power supply configured to supply power to the target holder, a controller configured to control the electric power supply and the substrate conveyer, and a target holder moving unit configured to move the target holder in a plane substantially parallel to a surface of the target holder, wherein the controller is configured to drive the substrate conveyer to convey the substrate and to drive the target holder moving unit to move the target holder while causing the electric power supply to supply power to the target holder.

### BACKGROUND OF THE INVENTION

1. Field of the Invention

The present invention relates to a magnetron sputtering apparatus.

2. Description of the Related Art

Sputtering is used to form a thin film on a solar cell substrate, a large area substrate for a flat panel display, or the like. In particular, a magnetron sputtering apparatus including a magnet unit arranged on the back side of a target set on a target holder is widely used because of the improved target utilization, plasma stability, and easy target upsizing. Especially for the solar cell substrate, a conveyance deposition method is often used to perform deposition for continuously arranged substrates in a sputtering chamber while conveying them at a predetermined speed, thereby implementing mass deposition.

In the magnetron sputtering apparatus, the magnetic field of the magnet unit generates a high density plasma near the target surface so that the target in the high density plasma region mainly sputters. In the magnetron sputtering apparatus of the conveyance deposition method, normally, the sputtering power is constant, and the target continuously ejects a predetermined amount of sputtered atoms to perform continuous deposition on the large area substrate. When the magnet unit is fixed, the high density plasma region is also at rest. However, since the substrate is conveyed at a predetermined speed, the thickness of the film deposited on the substrate is uniform in the conveyance direction.

On the other hand, for example, Japanese Patent Laid-Open No. 4-17671 discloses a magnetron sputtering apparatus that moves the magnet unit on the back side of a fixed flat target to increase the target utilization. In the magnetron sputtering apparatus of the conveyance deposition method, however, when the magnet unit moves (for example, reciprocates) in the substrate conveyance direction, the film formed on the substrate may be a nonuniform film alternately having a thick region and a thin region in the conveyance direction.

Various methods are disclosed to suppress this film thickness nonuniformity. The simplest method is increasing the moving speed of the magnet unit to some degree. FIG. 9 illustrates an example of the relationship between the reciprocating period of the magnet unit and the thickness distribution in the conveyance direction calculated by the present inventor. The thickness distribution in the conveyance direction is actually determined by the product of the reciprocating period of the magnet unit and the substrate conveyance speed. Hence, the product of the substrate conveyance speed and the reciprocating period of the magnet unit are plotted along the abscissa of FIG. 9. The abscissa represents the substrate moving distance during one reciprocation of the magnet unit. If the moving distance exceeds about 60 mm on the abscissa, the thickness distribution in the conveyance direction gradually deteriorates. When the reciprocating period of the magnet unit is determined to make the moving distance equal to or shorter than about 60 mm on the abscissa, the film thickness in the conveyance direction becomes uniform.

Recently, the substrate conveyance speed is increasing because the productivity is improved. Hence, to obtain a uniform thickness distribution in the conveyance direction, the reciprocating period of the magnet unit needs to be shorter in inverse proportion to the increase in the substrate conveyance speed, as is apparent from the relationship shown in FIG. 9. That is, the moving speed of the magnet unit needs to be higher. For example, assume that the substrate conveyance speed is 60 mm/s, and the one-way moving amount of the magnet unit that reciprocates at a uniform velocity is 100 mm. In this case, to uniform the film thickness in the conveyance direction, the reciprocating period of the magnet unit is 1 sec, and the moving speed is 200 mm/s. In a large sputtering apparatus, the magnet unit is also large and sometimes weighs 100 kg or more. To move the magnet unit so fast, the magnet unit moving mechanism needs to be made larger, though it is difficult because of restrictions on the apparatus.

### SUMMARY OF THE INVENTION

The present invention provides a magnetron sputtering apparatus which improves the target utilization and the uniformity of the film thickness in the conveyance direction by a relatively simple arrangement.

One of the aspects of the present invention provides a magnetron sputtering apparatus comprising a process chamber, a substrate conveyer provided in the process chamber to convey a substrate, a target holder provided in the process chamber to hold a flat target, a magnet unit arranged on a back side of the target holder, an electric power supply configured to supply power to the target holder, a controller configured to control the electric power supply and the substrate conveyer, and a target holder moving unit configured to move the target holder in a plane substantially parallel to a surface of the target holder, wherein the controller is configured to drive the substrate conveyer to convey the substrate and to drive the target holder moving unit to move the target holder while causing the electric power supply to supply power to the target holder.

Further features of the present invention will become apparent from the following description of exemplary embodiments with reference to the attached drawings.

### BRIEF DESCRIPTION OF THE DRAWINGS

FIG. 1 is a schematic sectional view of a magnetron sputtering apparatus applicable to the present invention;

FIG. 2 is an enlarged sectional view of a target holder shown in FIG. 1;

FIG. 3 is an enlarged sectional view of a supply tube;

FIG. 4 is a front view of the apparatus viewed from a direction A in FIG. 1;

FIG. 5 is a plan view of a magnet unit shown in FIG. 1;

FIG. 6 is a plan view of an opening shield shown in FIG. 1;

FIG. 7 is a view for explaining the state of a high density plasma when no opening shield exists;

FIG. 8 is a view for explaining the state of a high density plasma when the opening shield exists; and

FIG. 9 is a graph for explaining the relationship between the thickness distribution and the reciprocating period of the magnet unit.

### DESCRIPTION OF THE EMBODIMENTS

The detailed example of the embodiment of the present invention will now be described with reference to the accompanying drawings.

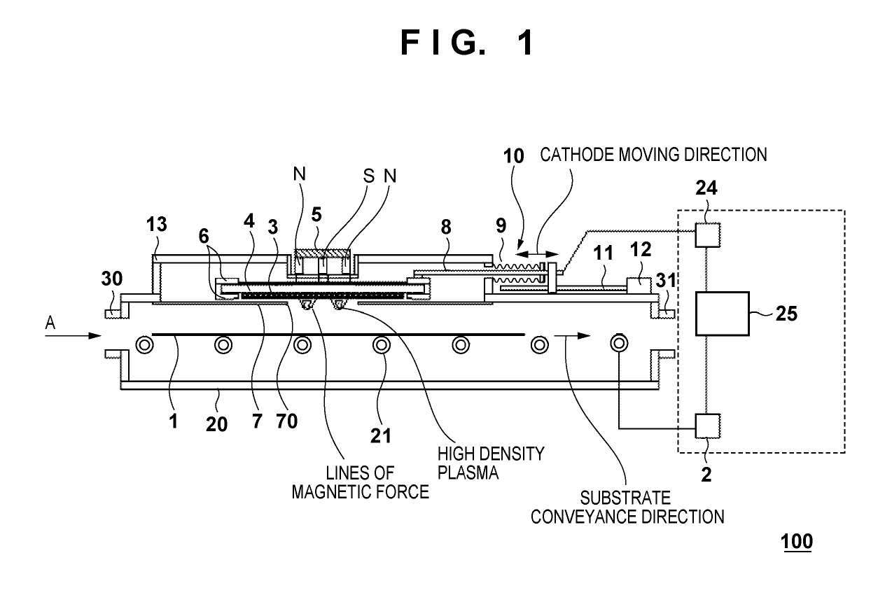

FIG. 1 is a schematic sectional view for explaining the overall arrangement of a magnetron sputtering apparatus applicable to the present invention. Normally, a plurality of chambers such as a load lock chamber, a buffer chamber, and an unload lock chamber are connected via gate valves to form one deposition chamber. Of this configuration, FIG. 1 illustrates only a magnetron sputtering apparatus. As shown in FIG. 1, a magnetron sputtering apparatus 100 includes a process chamber 20. The process chamber 20 includes a substrate conveyer 2 that conveys a substrate 1 at a controlled speed (predetermined speed, in this example), a flat target holder 4 provided in the process chamber 20 to set a flat target 3, an electric power supply 24 configured to supply power to the target holder 4, a magnet unit 5 arranged on the back side of the target holder 4, a target holder moving unit 10 that moves the target holder 4 in a plane almost parallel to its surface, a controller 25 configured to control the target holder moving unit 10, the electric power supply 24, and the substrate conveyer 2, and an opening shield 7 having an opening 70 and provided between the target 3 and the substrate 1.

The controller 25 executes computer programs stored in a storage medium and is configured to drive the substrate conveyer 2 to convey the substrate and also drive the target holder moving unit 10 to move the target holder 4 while causing the electric power supply 24 to supply power to the target holder 4. The magnet unit 5 is formed by combining, for example, an N-pole permanent magnet and an S-pole permanent magnet, and forms a loop-shaped magnetic field on the target 3.

The process chamber 20 has, in its sidewalls, an inlet port 30 to carry in the substrate 1 and an outlet port 31 to carry out the substrate 1. The substrate 1 carried in from the inlet port 30 is typically conveyed by the substrate conveyer 2 at a predetermined speed from left to right of FIG. 1 without stop while being held horizontally, and then carried out from the outlet port 31. During this time, sputter deposition is done on the upper surface of the substrate 1 by the target 3.

The conveyance deposition method where substrates are carried in one after another at a predetermined interval is generally advantageous in that uniform deposition can be performed for a large substrate using a relatively small target and magnet unit as well as in that a lot of substrates can efficiently undergo deposition. The lengths of the target and the magnet unit in the substrate conveyance direction can be shorter than the length of the substrate.

The substrate conveyer 2 can include a plurality of rotating rollers 21 arranged at equal intervals. In FIG. 1, the substrate 1 is directly placed on the rollers 21 and conveyed. However, the substrate 1 may be placed on a substrate holding member such as a tray and conveyed. When placing the substrate 1 on a tray, a number of relatively small substrates may be placed on one tray for deposition. Note that the substrate 1 of this example has a flat rectangular shape. However, the present invention is not limited to this. The substrate may be flat and circular or elliptical, or have a flat shape with steps or a tapered portion at the edge.

The process chamber 20 is evacuated to a vacuum state (low pressure) by a vacuum pump (not shown). A process gas (for example, Ar gas) is supplied to the process chamber 20 up to a predetermined pressure through a gas piping (not shown).

The target holder 4 faces the upper surface of the substrate 1. The flat target 3 is held by the target holder 4. The flat target 3 can be a rectangle having short sides along the substrate conveyance direction and long sides along the direction perpendicular to the substrate conveyance direction. The long sides of the flat target 3 are longer than the length of the substrate in the direction perpendicular to the substrate conveyance direction.

The target holder moving unit 10 can move the target holder 4 along the substrate conveyance direction. This allows the relative positions of the flat target 3 and the magnet unit 5 to be changed and thus use almost the whole region of the flat target 3. The target holder 4 is arranged in the process chamber 20 in the vacuum state and connected to a supply tube 8. The supply tube 8 is connected, via a bellows 9, to a ball screw 11 installed in the atmosphere outside the process chamber 20. A motor 12 is provided at the end of the ball screw 11 so that the target holder 4 can be moved by driving the motor 12. Note that in this example, the movement is a uniform reciprocating motion or a simple harmonic motion along the substrate conveyance direction. However, the present invention is not limited to this. The movement may be movement from a given point to another point along the substrate conveyance direction or rotation along the substrate conveyance direction. Note that the target holder 4 need not always move in the substrate conveyance direction, and may move in any direction within a plane almost parallel to the surface of the flat target holder. For example, the moving method that combines the substrate conveyance direction and the direction perpendicular to it may allow to further uniform erosion of the flat target.

A power cable and a pipe for cooling water (neither are shown) run through the supply tube 8 so that the electric power supply 24 can supply power to the target holder 4, or a temperature adjuster (not shown) can supply cooling water to the target holder.

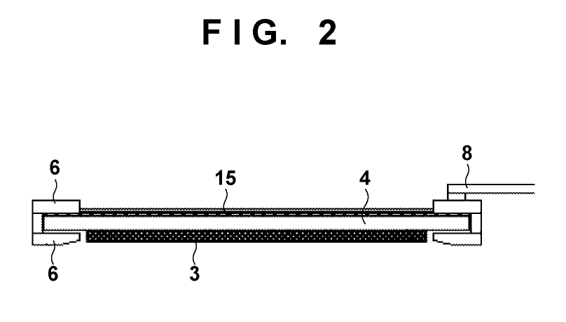

FIG. 2 is an enlarged sectional view of the target holder 4 shown in FIG. 1. The target holder 4 is also called a backing plate. The flat target 3 is set on the flat target holder 4 by bonding or the like.

The target holder 4 is fixed in a target shield 6, that is normally grounded, using insulating screws or the like via a target insulating plate 15 made of an insulating material on the back side so as to maintain insulation. The target shield 6 covers the two ends of the target holder 4 and the side surfaces of the target 3 at an interval of 2 to 3 mm from the flat target 3 and the target holder 4.

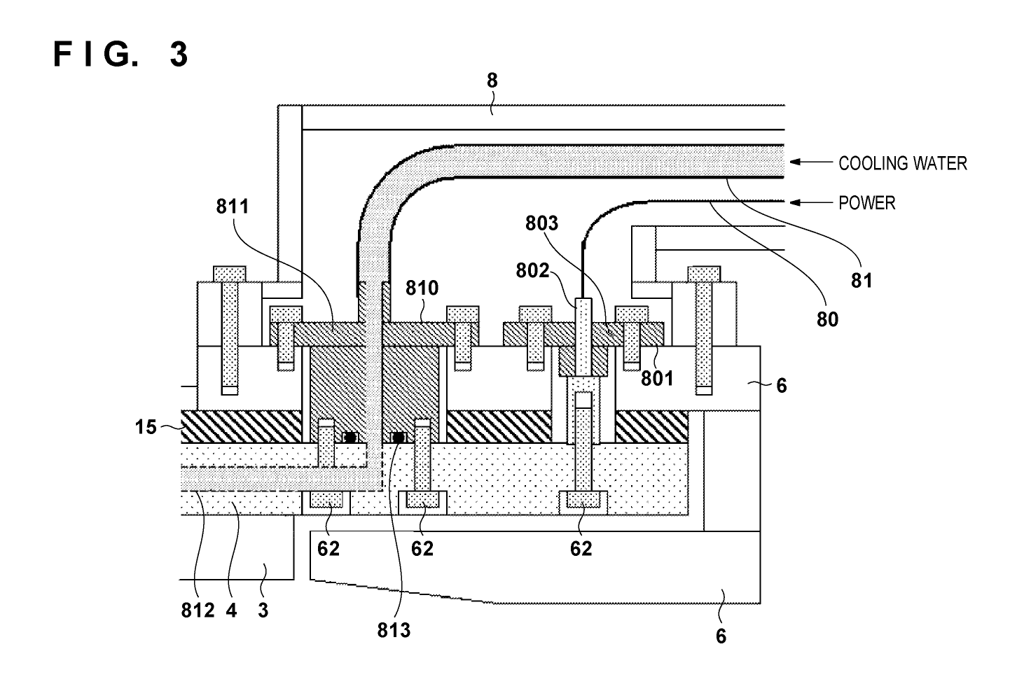

FIG. 3 is an enlarged sectional view of the supply tube 8. Note that FIG. 3 illustrates only the inlet of the cooling water path, although it has an inlet and an outlet. A power cable 80 and a cooling water tube 81 are provided in the supply tube 8. The supply tube 8 is vacuum. The power cable 80 can supply power to the target holder 4 via a power lead-in metal portion 802. The power lead-in metal portion 802 is fixed to the target shield 6 via a metal lead-in portion 801. On the other hand, the cooling water tube 81 is connected to a waterway 812 provided inside the target holder 4 through the internal piping of a cooling water introduction portion 810. Cooling water flowing through the waterway 812 can cool the target 3. When exchanging the target 3, three bolts 62 are unfastened to detach the cooling water introduction portion 810 and the metal lead-in portion 801 from the target holder 4. After a new target has been set, the cooling water introduction portion 810 and the metal lead-in portion 801 are connected to the target holder 4 by the three bolts 62.

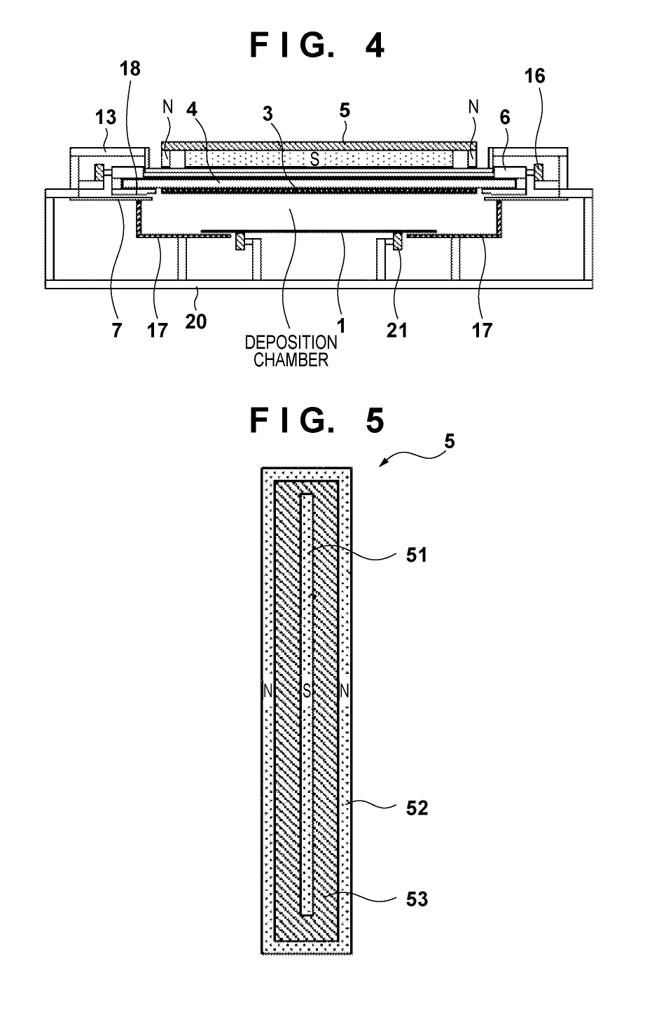

FIG. 4 is a front view of the apparatus viewed from a direction A in FIG. 1. The substrate conveyance direction is perpendicular to the drawing surface. The target shield 6 holding the target holder 4 is supported by target holder rollers 16 on both sides of the target shield 6 so as to be movable in the substrate conveyance direction. The magnet unit 5 is permanently arranged at a position on the back side of the flat target 3, for example, at a position outside (that is, on the atmosphere side) of a chamber wall 13. A pair of L-shaped shields 17 are provided in the process chamber 20 to prevent deposition on the chamber wall 13.

FIG. 5 is a plan view of the magnet unit 5 in FIG. 1 when viewed from the substrate side. The magnet unit 5 includes a ferromagnetic yoke 53, a center pole 51 formed from a permanent magnet having the S-pole on the target side, and an outer pole 52 formed from a permanent magnet having the N-pole on the target side and surrounding the center pole 51. The magnet unit 5 is, for example, a rectangle having short sides along the substrate conveyance direction. The short sides of the magnet unit 5 can be shorter than those of the target. The long sides of the magnet unit 5 can almost equal those of the target.

In this embodiment, since the magnet unit 5 is fixed, the position of the high density plasma constrained by the lines of magnetic force near the target surface as shown in FIG. 1 does not change even when the target holder 4 moves. Hence, the ejection position of sputtered atoms ejected from the target does not change, and a film having a uniform film thickness in the conveyance direction is deposited on the substrate conveyed at a predetermined speed.

At this time, the target holder 4 is moved to improve the target utilization. However, the moving speed of the target holder 4 and the film thickness uniformity have no relationship. The moving speed of the target holder 4 can be constant even when the substrate conveyance speed increases. For example, the reciprocating period of the target holder 4 can be about 10 to 100 sec. Even if the one-way moving amount is 100 mm, that is, the reciprocal moving amount is 200 mm, the moving speed can be as relatively low as 2 to 20 mm/s. For this reason, the load on the target holder moving unit 10 is small, and the manufacture is easy.

The opening shield 7 will be described next. As shown in FIG. 1, the opening shield 7 that is grounded and has the opening 70 is provided between the target 3 and the substrate 1 and fixed to the process chamber 20. The position of the opening 70 of the opening shield 7 corresponds to the position of the magnet unit 5. The opening 70 does not block the high density plasma generated near the surface of the target 3. The sputtered atoms can pass through the opening 70 and deposit on the substrate 1 to form a film. The opening shield 7 can be installed at a position relatively close to the target so as to function as the anode of the high density plasma.

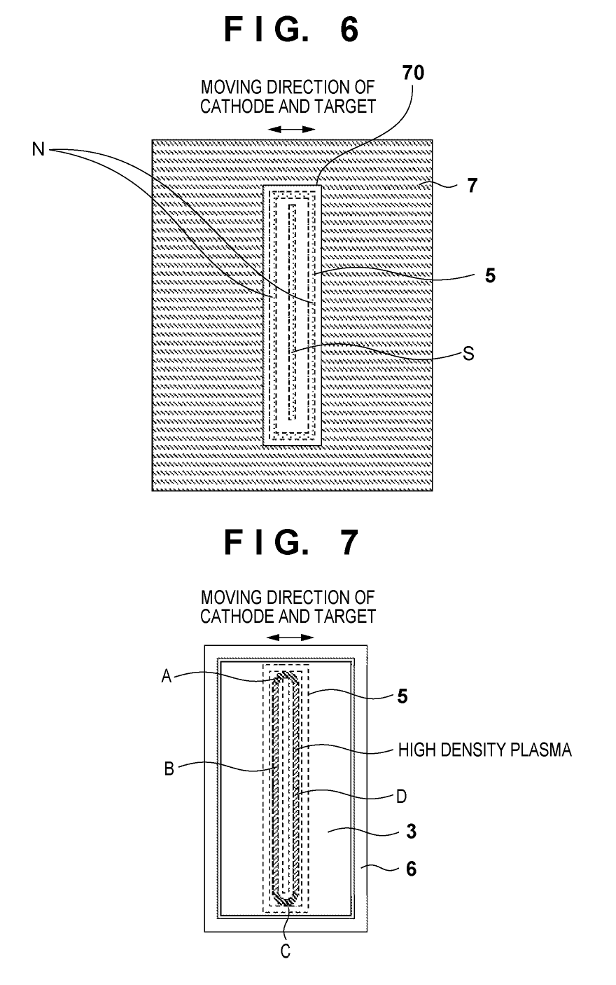

FIG. 6 is a plan view of the opening shield 7 viewed from the substrate side. Note that the target 3 and the target holder 4 are not illustrated in FIG. 6 for the descriptive convenience. The opening shield 7 can be an annular rectangular shield. The opening 70 can have almost the same shape and size as those of the magnet unit. Hence, the area of the opening 70 is normally smaller than that of the target 3. The opening shield 7 is so arranged that the magnet unit 5 is located on the opening 70. Note that although not illustrated in FIG. 6, the target holder 4 and the target 3 move between the opening shield 7 and the magnet unit 5.

An effect of the opening shield 7 will be explained next. Note that from the viewpoint of improving the target utilization, the opening shield 7 is not essential in the present invention. However, the opening shield 7 is important to solve the following problem that arises when employing the target holder moving unit 10 to move the target holder 4.

Erosion occurs on the surface of the target 3 upon sputtering. However, even when a relatively uniform erosion region is formed by moving the target holder 4, a non-erosion region may be formed to some extent on the outer periphery of the target. The non-erosion region is a region where the target is rarely sputtered. Hence, the sputtered atoms turn back to the target and deposit to form a film in that region. When the film thickness increases to some degree, the film may peel off the target to form particles. When manufacturing a solar cell or the like, particles in 0.1 mm or more are regarded as problems. Hence, the dropping particles are more problematic than the floating particles.

In this embodiment, sputtering is performed while moving the target holder 4. Hence, the particles readily vibrate as compared to the apparatus with a fixed target holder disclosed in Japanese Patent Laid-Open No. 4-17671. For this reason, film peeling from the non-erosion region of the target easily occurs, and the particles drop onto the substrate at a high probability.

The opening shield 7 is installed between the target 3 and the substrate 1 to receive many particles dropping from the target 3, thereby preventing them from reaching the substrate. The area of the opening 70 of the opening shield 7 is smaller than that of the target. In addition, the regions where film peeling from the target occurs concentrate to the outer periphery of the target. It is therefore possible to reduce the particles that reach the substrate through the opening.

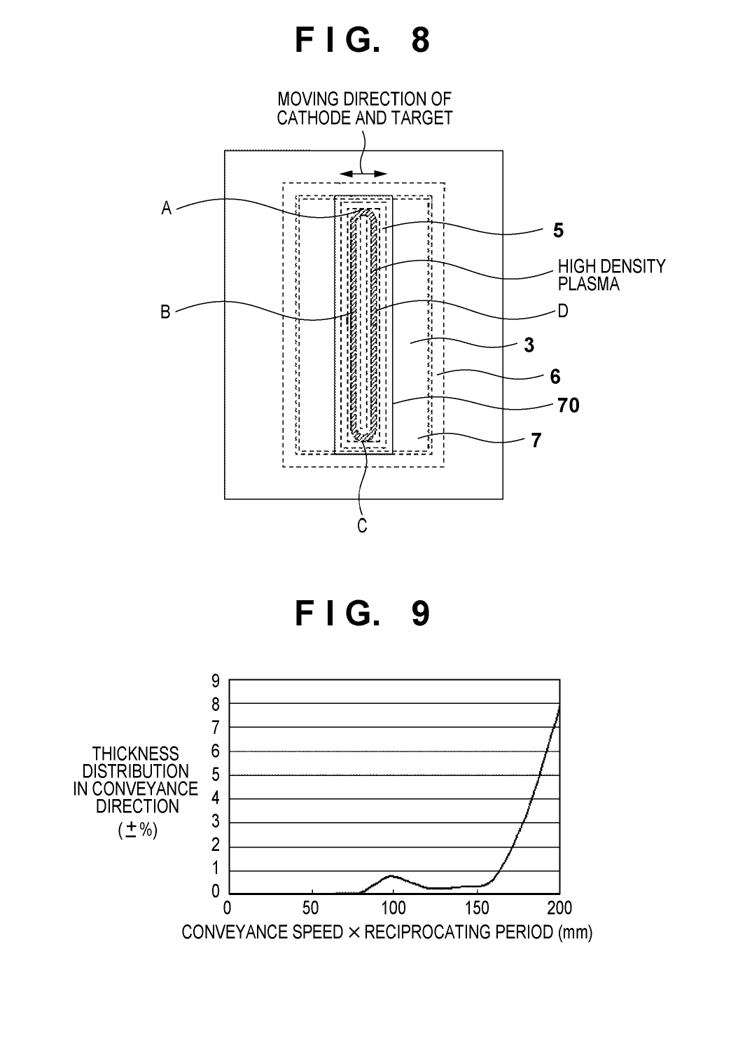

Another effect of the opening shield 7 will be explained next with reference to FIGS. 7 and 8. FIG. 7 is a view for explaining the state of the plasma when the opening shield 7 does not exist. FIG. 8 is a view for explaining the state of the plasma when the magnetron sputtering apparatus including the opening shield 7, as shown in FIG. 1, is used. As shown in FIG. 7, loop-shaped lines of magnetic force are formed near the surface of the target 3 between the outer pole and the center pole of the magnet unit 5, and the high density plasma is distributed in a ring shape near the target surface due to the drift motion of electrons. Since the magnet unit 5 has a long rectangular shape, the high density plasma is also distributed in a long elliptical ring shape.

The high density plasma is distributed in the elliptical ring shape, as described above, and the plasma density may be uneven. It is known by the present inventor's experience that the ring-shaped high density plasma generated by DC magnetron sputtering increases its density near a grounded member, that is, an anode. For example, since the grounded target shield 6 is arranged at the outer periphery of the target 3 so as to surround the target 3, the density of the ring-shaped high density plasma becomes higher near the target shield 6. FIG. 7 illustrates the magnet unit 5 located at the center of the target 3. At this time, the plasma density is higher in regions A and C than in regions B and D.

If the density of the ring-shaped high density plasma becomes nonuniform, the target erosion is also nonuniform accordingly. Hence, the target regions corresponding to A and C erode more deeply than the target regions corresponding to B and D in FIG. 7. Similar erosion nonuniformity generally occurs when the magnet unit 5 exists in a place other than the ends of the target 3, and the portions that partially erode deeply may finally lower the target utilization.

In addition, when the target holder 4 moves, the position of the grounded target shield 6 relative to the high density plasma changes. Hence, the nonuniformity of the high density plasma changes as the target holder 4 moves. This may cause nonuniformity of the thickness and quality of the film deposited on the substrate.

On the other hand, as shown in FIG. 8, when the stationary opening shield 7 that is grounded and has the opening is present between the target 3 and the substrate 1, the grounded opening shield 7, that is, the anode always exists near the outer periphery of the ring-shaped high density plasma even when the target holder 4 moves, and density nonuniformity hardly occurs in the ring-shaped high density plasma. Hence, nonuniform erosion of the target 3 hardly occurs in the elliptic region, and the target utilization rises. In addition, even when the target holder 4 moves, the anode position remains unchanged with respect to the high density plasma. Hence, discharge stabilizes because the density distribution of the ring-shaped high density plasma does not change. This leads to improvement of the thickness and quality of the film deposited on the substrate.

A method of manufacturing an electronic device using the magnetron sputtering apparatus of this embodiment will be described next. A process gas such as Ar gas is introduced into the evacuated chamber up to a predetermined pressure. The target holder moving unit 10 continuously reciprocates the target holder 4 in the substrate conveyance direction. Cooling water is supplied to the target holder 4 through the supply tube 8.

The controller 25 operates the electric power supply 24 to make it supply DC power to the target holder 4 via the supply tube 8, thereby performing magnetron sputtering. At the same time, the controller 25 executes the deposition process while driving the substrate conveyer 2 to convey the substrate 1 at a predetermined speed. The controller 25 also drives the target holder moving unit 10 to move the target holder 4 while supplying power to the target holder 4.

This makes it possible to form, on the substrate, a film having a uniform thickness and quality at least in the conveyance direction. Additionally, target erosion is also relatively uniform, and the target utilization rises.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-253855, filed Nov. 12, 2010, which is hereby incorporated by reference herein in its entirety.

What is claimed is:

1. A magnetron sputtering apparatus comprising:
a process chamber;
a substrate conveyer provided in the process chamber to convey a substrate;
a target holder provided in the process chamber to hold a flat target;
a magnet unit arranged on a back side of the target holder;
an electric power supply configured to supply power to the target holder;
a controller configured to control the electric power supply and the substrate conveyer; and
a target holder moving unit configured to move the target holder in a plane substantially parallel to a surface of the target holder,
wherein the controller is configured to drive the substrate conveyer to convey the substrate and to drive the target holder moving unit to move the target holder while causing the electric power supply to supply power to the target holder.

2. The apparatus according to claim 1, further comprising an opening shield permanently provided between the target holder and the substrate conveyer, the opening shield being grounded and having an opening smaller than an area of the flat target.

3. The apparatus according to claim 1, wherein the controller causes the substrate conveyer to convey the substrate at a predetermined speed.

4. The apparatus according to claim 1, wherein the magnet unit is arranged outside the process chamber so that the target holder is sandwiched between the magnet unit and the substrate conveyer.

5. A magnetron sputtering apparatus comprising:
a process chamber;
a substrate conveyer configured to convey a substrate in the process chamber;
a target holder configured to hold a flat target in the process chamber;
a magnet unit arranged so that the target holder is sandwiched between the magnet unit and the substrate conveyer; and
a target holder moving unit configured to move the target holder along a plane to change relative positions of the flat target and the magnet unit.

6. The apparatus according to claim 5, wherein the plane is substantially parallel to a surface of the flat target.

7. The apparatus according to claim 5, wherein the magnet unit is arranged outside the process chamber.
